(19) United States
(12) Patent Application Publication
(10) Pub. No.: US 2014/0327129 A1
(43) Pub. Date: Nov. 6, 2014

(54) PACKAGE ON PACKAGE DEVICE AND METHOD OF MANUFACTURING THE SAME

(71) Applicants: Eunseok CHO, Suwon-si (KR); Heejung HWANG, Suwon-si (KR)

(72) Inventors: Eunseok CHO, Suwon-si (KR); Heejung HWANG, Suwon-si (KR)

(21) Appl. No.: 14/226,981

(22) Filed: Mar. 27, 2014

(30) Foreign Application Priority Data
May 2, 2013 (KR) 10-2013-0049506

(51) Int. Cl. H01L 23/34; H01L 25/18

(52) U.S. Cl. CPC H01L 23/34; H01L 25/18
USPC 257/713

(57) ABSTRACT

Provided is a package on package (PoP) device and a method of manufacturing the same. In the PoP device, a thermal interface material layer is interposed between a lower semiconductor chip and an upper package substrate, and a heat sink is disposed on an upper semiconductor package substrate. This maximizes heat release. Accordingly, an operation speed can be improved and malfunction limitation can be solved.

### CROSS-REFERENCE TO RELATED APPLICATIONS

This U.S. non-provisional patent application claims priority under 35 U.S.C. §119 from Korean Patent Application No. 10-2013-0049506, filed on May 2, 2013, the entire contents of which are hereby incorporated by reference.

### BACKGROUND

1. Field

The present general inventive concept relates to a package on package device and a method of manufacturing the same.

2. Description of the Related Art

As electronic industries have evolved, requests for high functionality, high speed, and miniaturization of electronic components are increased. In response to this trend, methods of stacking and mounting various semiconductor chips on a single package substrate or stacking a package on another package is emerged as a current semiconductor mounting technology. Among these methods, since a package on package (PoP) device in which a package is stacked on another package includes semiconductor chips and a package substrate in each stacked package, the total package becomes thicker gradually. Furthermore, in relation to the PoP device, it is difficult to output, to the outside, heat which is generated within the semiconductor chips. This causes malfunctions of elements or delays in operation speeds, etc.

### SUMMARY

The present general inventive concept provides a package on package (PoP) device capable of improving heat release characteristics.

The present general inventive concept also provides a manufacturing method of a PoP device.

Additional features and utilities of the present general inventive concept will be set forth in part in the description which follows and, in part, will be obvious from the description, or may be learned by practice of the general inventive concept.

Exemplary embodiments of the present general inventive concept provide a package on package (PoP) device including a lower semiconductor package comprising a lower package substrate, and a lower semiconductor chip mounted on the lower package substrate, an upper semiconductor package having an upper package substrate disposed on the lower semiconductor package, and an upper semiconductor chip mounted on the upper package substrate, a first thermal interface material layer interposed between the lower semiconductor chip and the upper package substrate, and a heat sink disposed on the upper semiconductor chip.

In exemplary embodiments of the present general inventive concept, the PoP device may include a second thermal interface material layer interposed between the upper semiconductor chip and the heat sink.

In exemplary embodiments of the present general inventive concept, the second thermal interface material layer may directly border to the upper semiconductor chip.

In exemplary embodiments of the present general inventive concept, the upper semiconductor chip may include first and second upper semiconductor chips sequentially stacked, wherein the first upper semiconductor chip is mounted on the upper package substrate in a wire bonding method, and the second upper semiconductor chip is mounted on the first upper semiconductor chip in a flip chip bonding method.

In exemplary embodiments of the present general inventive concept, the first and second upper semiconductor chips may be identical to each other and symmetrically disposed on one another.

In exemplary embodiments of the present general inventive concept, the PoP device may further include an upper mold layer covering side surfaces of the upper package substrate and the upper semiconductor chip, and the upper mold layer may include an upper surface that is coplanar with an upper surface of the upper semiconductor chip.

In exemplary embodiments of the present general inventive concept, the upper semiconductor package may further include an upper mold layer covering the package substrate and the upper semiconductor chip and being interposed between the second thermal interface material layer and the upper semiconductor chip.

In exemplary embodiments, the first and second thermal interface material layers may include an adhesion layer, a thermal grease, or a thermal epoxy, and at least one of the first and second thermal interface material layers comprises metal solid particles.

In exemplary embodiments of the present general inventive concept, the lower semiconductor package may further include a lower mold layer covering side surfaces of the lower package substrate and the lower semiconductor chip, wherein the lower mold layer comprises an upper surface that is coplanar with an upper surface of the lower semiconductor chip.

In exemplary embodiments of the present general inventive concept, the heat sink may be extended to cover side surfaces of the upper and lower semiconductor packages.

In exemplary embodiments of the present general inventive concept, the heat sink may include a plurality of protruding pins.

In exemplary embodiments of the present general inventive concept, the lower semiconductor chip may be a logic chip, and the upper semiconductor chip is a memory chip.

Exemplary embodiments of the present general inventive concept may provide methods of manufacturing a package on package (PoP) device, the methods including manufacturing a lower semiconductor package comprising a lower package substrate, a lower semiconductor chip disposed on the lower package substrate, and lower solder bumps disposed on the lower package substrate and separated from the lower semiconductor chip, manufacturing an upper semiconductor package comprising an upper package substrate, an upper semiconductor chip disposed on the upper package substrate, and upper solder bumps disposed on a lower surface of the upper package substrate, forming a heat sink on the upper semiconductor package, forming a thermal interface material layer on the lower semiconductor chip, and arranging the thermal interface material layer so as to be in connect with the upper package substrate, and fusing the lower solder bumps and the upper solder bumps to form connection solder bumps.

In exemplary embodiments of the present general inventive concept, the manufacturing of the lower semiconductor package may include, forming an upper mold layer covering the upper package substrate and the upper semiconductor chip, and performing a polishing process to remove at least some of the upper mold layer and expose at least some of the upper semiconductor chip.

In exemplary embodiments of the present general inventive concept, the forming of the heat sink may include attaching the heat sink on the upper semiconductor chip.

Exemplary embodiments of the present general inventive concept may also provide a method of manufacturing a package on package (PoP) device, the method including forming a lower package substrate, and mounting a lower semiconductor chip on the lower package substrate so as to form a lower semiconductor package, forming an upper package substrate, mounting an upper semiconductor chip on the upper package substrate so as to form an upper semiconductor package, disposing the upper package substrate of the upper semiconductor package on the lower semiconductor package so as to interpose a first thermal interface material layer between the lower semiconductor chip and the upper package substrate, and forming a heat sink on the upper semiconductor chip.

Exemplary embodiments of the present general inventive concept may also provide an electronic apparatus having a memory device comprising a package on package (PoP) device including a lower semiconductor package comprising a lower package substrate, and a lower semiconductor chip mounted on the lower package substrate, an upper semiconductor package comprising an upper package substrate disposed on the lower semiconductor package, and an upper semiconductor chip mounted on the upper package substrate, a first thermal interface material layer interposed between the lower semiconductor chip and the upper package substrate, and a heat sink disposed on the upper semiconductor chip, and a controller electrically connected to at least one of the lower semiconductor package and the upper semiconductor package to read from and write to at least one of the lower semiconductor chip and the upper semiconductor chip.

The electronic apparatus may further include first lower solder bumps disposed on the lower package substrate so as to be interposed between an upper surface of the lower package substrate and a lower surface of the extended sides of the heat sink to electrically connect the lower package substrate and the heat sink.

The electronic apparatus may further include a second thermal interface layer that is interposed between the upper semiconductor chip and the heat sink.

The electronic apparatus may include where the heat sink covers side surfaces of the upper and lower semiconductor packages.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view illustrating a package on package (PoP) device according to an embodiment of the present general inventive concept;

FIGS. 2 to 7 are cross-sectional views sequentially illustrating processes of manufacturing the PoP device having the cross-sectional view of FIG. 1;

FIG. 8 is a cross-sectional view illustrating a PoP device according to an exemplary embodiment of the present general inventive concept;

FIGS. 9 to 13 are cross-sectional views sequentially illustrating processes of manufacturing of the PoP device having the cross-sectional view of FIG. 8;

FIGS. 14 to 16 are cross-sectional views illustrating a PoP device according to an exemplary embodiment of the inventive concept;

FIG. 17 illustrates an exemplary package module including a semiconductor package to which an exemplary embodiment of the present general inventive concept is applied;

FIG. 18 is a block diagram illustrating an exemplary electronic device including a semiconductor package to which an exemplary embodiment of the present general inventive concept is applied; and

FIG. 19 is block diagram illustrating an exemplary memory system including a semiconductor package to which an exemplary embodiment of the present general inventive concept is applied.

### DETAILED DESCRIPTION OF THE EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In the drawings, the dimensions of layers and regions are exaggerated for clarity of illustration. It will also be understood that when an element is referred to as being ‘on’ another element, it can be directly on the other element, or intervening elements may also be present. Further, it will be understood that when an element is referred to as being ‘under’ another element, it can be directly under, and one or more intervening elements may also be present. In addition, it will also be understood that when an element is referred to as being ‘between’ two elements, it can be the only element between the two elements, or one or more intervening elements may also be present.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like reference numerals refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. Thus, the regions illustrated in the figures are schematic in nature and their shapes may be not intended to illustrate the actual shape of a region of a device and are not intended to limit the scope of example embodiments.

Hereinafter, exemplary embodiments of the present general inventive concept will be described in detail with reference to the accompanying drawings.

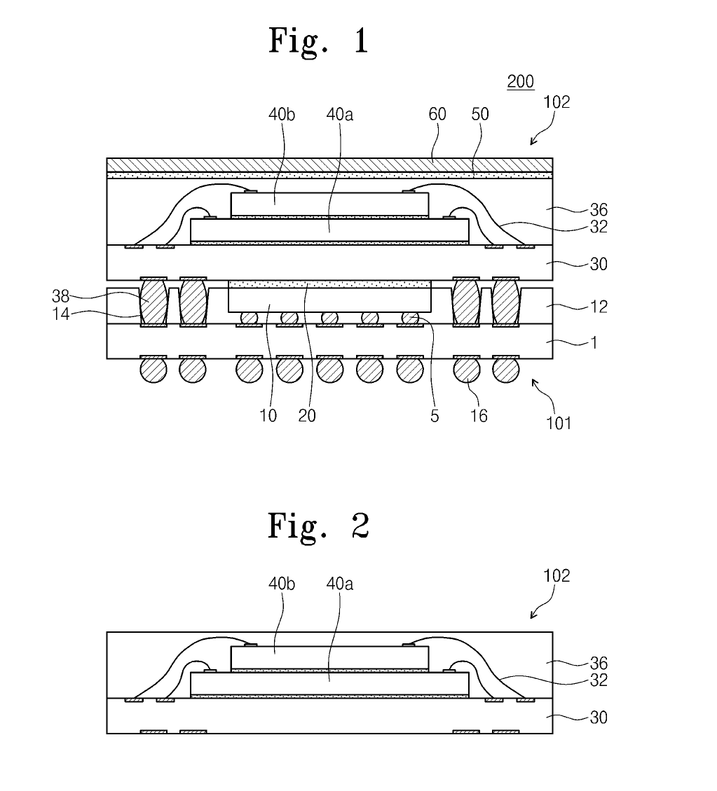

FIG. 1 illustrates a cross-sectional view of a package on package (PoP) device according to an exemplary embodiment of the present general inventive concept.

Referring to FIG. 1, the PoP device 200 according to exemplary embodiments of the present general inventive concept includes a lower semiconductor package 101 and an upper semiconductor package 102.

The lower semiconductor package 101 includes a lower package substrate 1, a lower semiconductor chip 10 mounted on the lower package substrate 1, and a lower mold layer 12 covering these. That is, the lower mold layer 12 covers the lower package substrate 1, and at least a portion of the lower semiconductor chip 10. A first thermal interface material layer 20 may cover an upper surface of the lower semiconductor chip 10, and the lower mold layer 12 may cover the other sides of the lower semiconductor chip 10. The lower semiconductor chip 10 is electrically connected to the lower package substrate 1 by using first lower solder bumps 5, and may be mounted in a flip chip bonding method. On a side (e.g., the lower side) of the lower package substrate 1, second lower solder bumps 16 are disposed. As described above, the lower mold layer 12 covers side walls of the lower semiconductor chip 10, but exposes the upper surface of the lower semiconductor chip 10. That is, the upper surface of the lower semiconductor chip 10 may not be covered by the lower mold layer 12. The lower mold layer 12 includes connection holes 14 separated from the lower semiconductor chip 10. The lower semiconductor chip 10 may be, for example, a logic chip, a processor, a central processing unit, a programmable logic device, or a field programmable gate array, and/or any suitable semiconductor chip.

The upper semiconductor package 102 includes an upper package substrate 30, upper semiconductor chips 40a and 40b mounted on the upper package substrate 30, and an upper mold layer 36 covering these. That is, the upper mold layer 36 may cover the upper semiconductor chips 40a and 40b, as well as the upper package substrate 30. The upper semiconductor chips 40a and 40b include a first upper semiconductor chip 40a and a second semiconductor chip 40b. The upper semiconductor chips 40a and 40b may be mounted on the upper package substrate 30 in a wire bonding method. The upper semiconductor chips 40a and 40b may be, for example, memory chips.

The upper semiconductor package 102 is stacked on the lower semiconductor package 101, with the upper semiconductor package 102 and the lower semiconductor package 101 electrically connected to each other by connection solder bumps 38. The connection solder bumps 38 are disposed in the connection holes 14.

The first thermal interface material layer 20 is interposed between the lower semiconductor chip 10 and the upper package substrate 30. On the upper semiconductor package 102, a second thermal interface material layer 50 and a heat sink 60 are sequentially disposed. That is, the second thermal interface material layer 50 is disposed on the upper mold layer 36, and the heat sink 60 is disposed on the second thermal interface material layer 50. The second thermal interface material layer 50 borders the upper mold layer 36, and may be separated from the second upper semiconductor chip 40b. The thermal interface material layers 20 and 50 include at least one of an adhesion layer, a thermal grease, and/or a thermal epoxy, and at least one of these may include metal sold particles. The heat sink 60 may be a metal plate or a metal tape having flexibility. In the PoP device 200, the first thermal interface material layer 20 is interposed between the lower semiconductor chip 10, which is a logic chip that can generating heat, and the upper package substrate 30. When the lower semiconductor chip 10 and the upper package substrate 30 are separated from each other without the first thermal interface material layer 20, air exists in a space between them. Thermal conductivity of a gas such as air is significantly lower than that of a solid. Accordingly, when there is no first thermal interface material layer 20, heat generated from the lower semiconductor chip 10 is not efficiently released. However, in the present general inventive concept, since the first thermal interface material layer 20 is interposed (i.e. the first thermal interface material layer 20 is interposed between the upper package substrate 30 and the lower semiconductor chip 10), the heat generated from the lower semiconductor chip 10 may be transferred to the upper semiconductor package 102 through the first thermal interface material layer 20, and to the heat sink 60 through at least the second thermal interface material layer 50 to maximize heat release. That is, having the first thermal interface material layer 20 interposed between the upper package substrate 30 and the lower semiconductor chip 10 may increase the heat transfer (e.g., compared to a gas such as air between the upper package substrate 30 and the lower semiconductor chip 10) from the lower semiconductor chip to the heat sink 60.

Accordingly, an operation speed of at least one of the lower semiconductor chip 10, and the upper semiconductor chips 40a and 40b of the PoP device 200 can be improved and a malfunction limitation (e.g., a malfunction of one or more of the lower semiconductor chip and/or the upper semiconductor chips 40a and 40b due to heat buildup and/or overheating) may be reduced and/or solved. A dynamic thermal management (DTM) start time can be delayed so that use of a central processing unit that is coupled to and/or part of the PoP device can be maximized. That is, as the package on package (PoP) devices of the present general inventive concept having the first thermal interface material layer 20, the second thermal interface material layer 50, and the heat sink 60 may maximize heat release from the PoP device such that the DTM may be delayed so that the use of a processor that is coupled to and/or part of the PoP device can be maximized.

FIGS. 2 to 7 are cross-sectional views sequentially illustrating processes of manufacturing the PoP device having a cross-sectional view of FIG. 1.

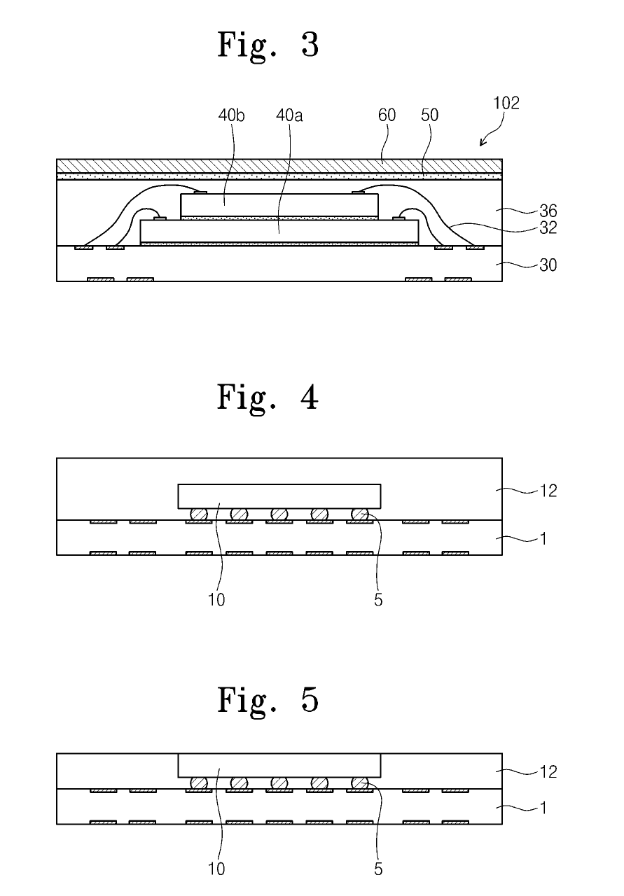

A method of forming the upper semiconductor package 102 is described with reference to FIGS. 2 and 3.

Referring to FIG. 2, the first upper semiconductor chip 40a and the second semiconductor package 40b are sequentially stacked and electrically connected by using a wire 32. A mold process is performed to form the upper mold layer 36 covering the upper semiconductor chips 40a and 40b.

Referring to FIG. 3, the second thermal interface material layer 50 is disposed on the upper mold layer 36 of the upper semiconductor package 102, and the heat sink 60 is disposed on the second thermal interface material layer 50. For example, the heat sink 60 may be attached on the upper semiconductor package 102 by using the second thermal interface material layer 50. The second thermal interface material layer 50 may be interposed between the upper mold layer 36 of the upper semiconductor package 102 and the heat sink 60.

Hereinafter, a method of manufacturing the lower semiconductor package 101 is described with reference to FIGS. 4 to 6.

Referring to FIG. 4, the lower semiconductor chip 10 is mounted on the lower package substrate 1 by using first lower solder bumps 5 in a flip chip bonding method. A mold process is performed to form a lower mold layer 12 covering the lower semiconductor chip 10 and the lower package substrate 1.

Referring to FIG. 5, a polishing process is performed to remove at least some of the upper portion of the lower mold layer 12 and expose the upper surface of the lower semiconductor chip 10. At this time, some of the upper portion of the lower semiconductor chip 10 is also removed together with the lower mold layer 12, which allows the lower semiconductor chip 10 to have a desired thickness.

Alternatively, without the polishing process, the lower mold layer 12 may be formed to expose the upper surface of the lower semiconductor chip 10 in the mold process.

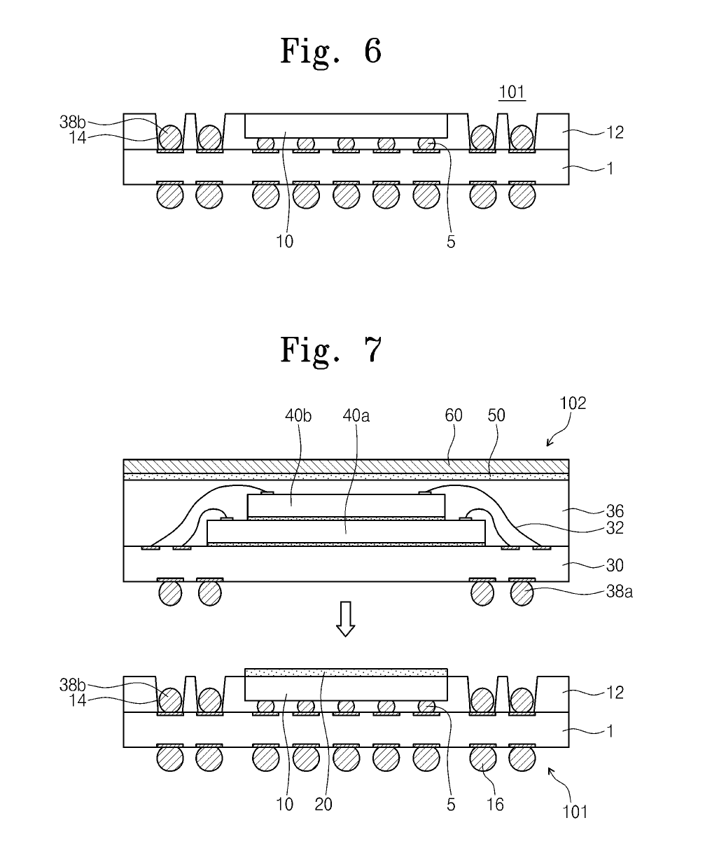

Referring to FIG. 6, second lower solder bumps 16 are attached to the lower of the lower package substrate 1, and connection holes 14 are formed in the lower mold layer 12 by using, for example, a laser. Lower connecting solder bumps 38b are formed on the lower package substrate 1, which is exposed by the connection holes 14. Accordingly, the lower semiconductor package 101 may be formed.

Referring to FIG. 7, upper connection solder bumps 38a are attached to a lower portion of the upper package substrate 30. The first thermal interface material layer 20 is formed on the lower semiconductor chip 10. The upper semiconductor package 102 of FIG. 3 is located on the lower semiconductor chip 10, with the first thermal interface material layer 20 interposed between the upper package substrate 30 of the upper semiconductor package 102 and the lower semiconductor chip 10 of the lower semiconductor package 101. The upper connecting solder bumps 38a of the upper semiconductor package 102 are inserted into connection holes 14 formed in the lower semiconductor package 101 so as to be disposed on the lower connecting solder bumps 38b. The upper connecting solder bumps 38a are heated to be fused with the lower connecting solder bumps 38b. Accordingly, the connection solder bumps 38 of FIG. 1 are formed. At this time, the first thermal interface material layer 20 borders and/or is coupled to the upper package substrate 30.

When the first thermal interface material layer 20 is formed from a thermal epoxy, at first, a liquid thermal epoxy resin is coated or dripped on the lower semiconductor chip 10, and the liquid thermal epoxy resin is cured in the heating process. Alternatively, when the first thermal interface material layer 20 is an adhesion layer, a distance between the lower semiconductor chip 10 and the upper package substrate 30 is predicted in a final structure to adjust the thickness of the first thermal interface material layer 20.

As described above, the PoP device 200 of FIG. 1 may be formed.

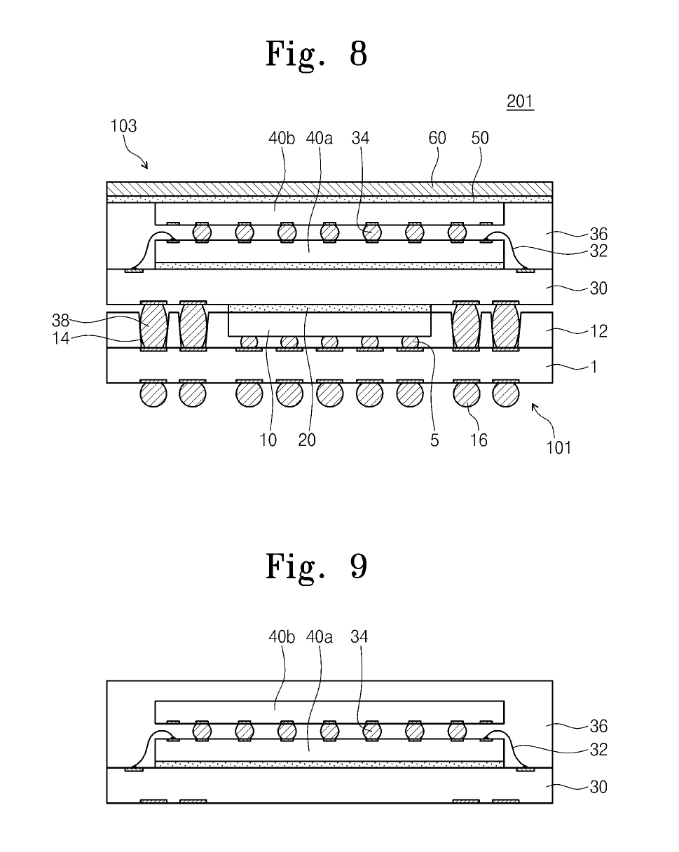

FIG. 8 illustrates a cross-sectional view of a PoP device according to an exemplary embodiment of the inventive concept.

Referring to FIG. 8, the PoP device 201 according to an exemplary embodiment of the present general inventive concept, upper semiconductor chips 40a and 40b may be the same and/or identical. The first upper semiconductor chip 40a may be mounted on the upper package substrate 30 by using a wire 32 in a wire bonding method. The second upper semiconductor chip 40b may be symmetrically mounted on the first upper semiconductor chip 40a by using upper solder balls 34 in a flip chip bonding method. The upper mold layer 36 exposes an upper surface of the second upper semiconductor chip 40b, covers side surfaces of the first and second upper semiconductor chips 40a and 40b, and may be interposed between these. That is, the upper mold layer 36 may be interposed between the first and second upper semiconductor chips 40a and 40b. A second thermal interface material layer 50 borders the upper surface of the second upper semiconductor chip 40b. The second thermal interface material layer 50 may be disposed on the second upper semiconductor chip 40b and the upper mold layer 36. In the present exemplary embodiment, since the second thermal interface material layer 50 directly borders to the second upper semiconductor chip 40b, a thermal release effect may be increased. That is, heat generated from the upper semiconductor chips 40a and/or 40b may be more efficiently dissipated when the second thermal interface material layer 50 directly borders to the second upper semiconductor chip 40b. Other configuration except these may be identical/similar to the above description in relation to FIG. 1.

FIGS. 9 to 12 are cross-sectional views sequentially illustrating processes of manufacturing the PoP device having the cross-sectional view of FIG. 8.

Referring to FIG. 9, the first upper semiconductor chip 40a is attached on the upper package substrate 30 and electrically connected to the upper package substrate 30 by using the wire 32. The second upper semiconductor chip 40b is mounted on the first upper semiconductor chip 40a by using upper solder bumps 34 in a flip chip bonding method. A mold process is performed to form an upper mold layer 36 covering the upper semiconductor chips 40a and 40b, and filling a space between these. That is, the upper mold layer 36 may be disposed on and between the upper semiconductor chips 40a and 40b.

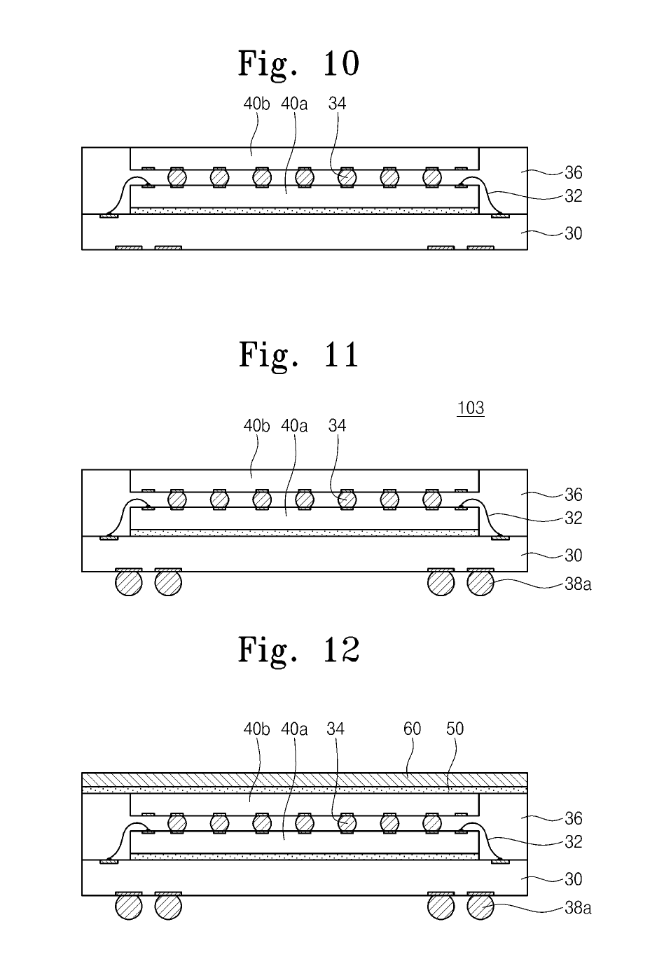

Referring to FIG. 10, a polishing process is performed to remove some of an upper portion of the upper mold layer 36 and expose an upper surface of the second upper semiconductor chip 40b. At this time, some of the upper portion of the second semiconductor chip 40b is removed to have a desired thickness.

Alternatively, without polishing process, a mold process is performed to allow the upper mold layer 36 to expose the upper portion of the second upper semiconductor chip 40b.

Referring to FIG. 11, upper connection solder bumps 38a may be attached to a lower portion of the upper package substrate 30. Accordingly, the upper semiconductor package 103 is formed.

Referring to FIG. 12, the second thermal interface material layer 50 is disposed on the upper mold layer 36 and the upper semiconductor chip 40b on the upper semiconductor package 103, and the heat sink 60 is disposed on the second thermal interface material layer 50. That is, the second thermal interface material layer 50 may be interposed between the heat sink 60 and the upper mold layer 36 and the upper semiconductor chip 40b. For example, the heat sink 60 may be attached on the upper semiconductor package 103 by using the second thermal interface material layer 50. Accordingly, an upper surface of the second upper semiconductor chip 40b borders the second thermal interface material layer 50.

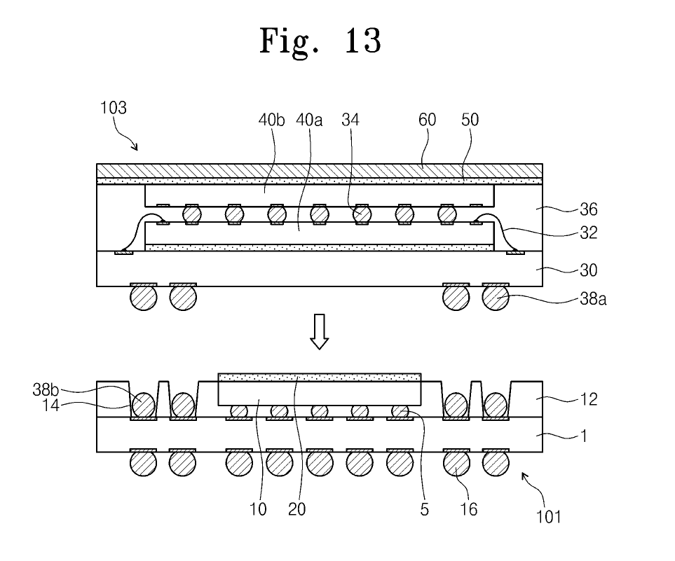

Referring to FIG. 13, the first thermal interface material layer 20 is formed on the lower semiconductor chip 10 in the lower semiconductor package 101, which is manufactured through processes illustrated in FIGS. 4 to 6. The upper semiconductor package 103 is disposed on the lower semiconductor package 101. The upper connection solder bumps 38a are inserted into the connection holes 14 formed in the lower mold layer 12 of the lower semiconductor package 101. The upper connection solder bumps 38a can be heated so as to be fused with the lower connection solder bumps 38b. Accordingly, the connection solder bumps 38 of FIG. 8 may be formed. At this time, the first thermal material layer 20 is formed to border the upper package substrate 30.

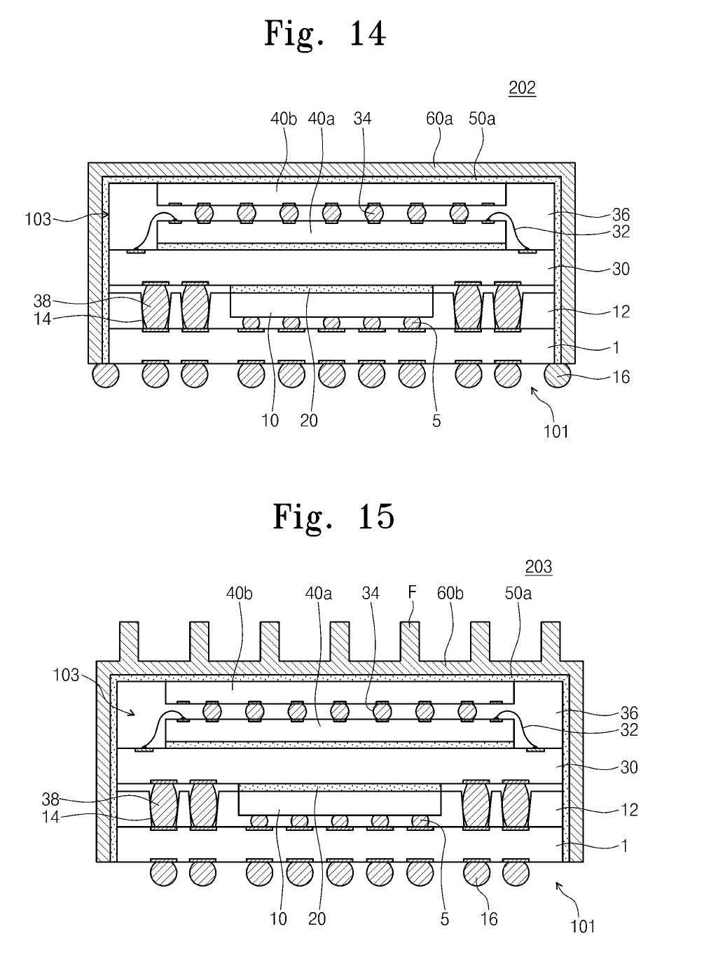

FIGS. 14 to 16 illustrate cross-sectional views of a PoP device according to exemplary embodiments of the present general inventive concept.

Referring to FIG. 14, in the PoP device 202 according to the exemplary embodiments of the present general inventive concept, the second thermal interface material layer 50a and the heat sink 60a are extended to cover side surfaces of the upper and lower semiconductor packages 101 and 103. Second lower solder bumps 16 may be attached to a lower surface of the heat sink 60a. In this case, a heat release effect in the PoP device 202 can increased over that of the PoP device 200 illustrated in FIG. 1. Description about other configuration may be identical/similar to that in relation to FIG. 1.

Referring to FIG. 15, in the PoP device 203 according to exemplary embodiments of the present general inventive concept, the heat sink 60b includes a plurality of pins F. In exemplary embodiments of the present general inventive concept, the heat sink 60b can include a plurality of fins, rather than the pins F. For example, the fins may be arranged longitudinally on the surface of the heat sink 60b so as to be parallel with one another. Since a heat releasing area can be increased due to the pins F and/or the fins, the heat releasing effect of PoP device 203 can be further increased over that of the PoP device 200 illustrated in FIG. 1, the PoP device 201 illustrated in FIG. 8, and the PoP device 202 illustrated FIG. 14. Description about other configuration may be identical/similar to that in relation to FIG. 14.

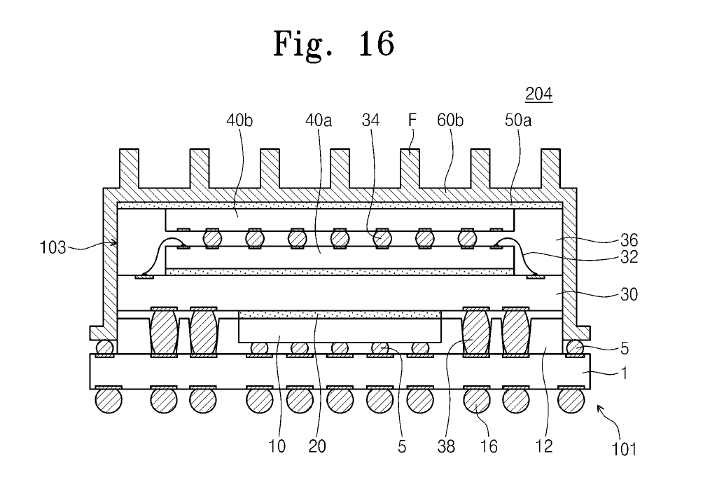

Referring to FIG. 16, in the PoP device 204 according to exemplary embodiments of the present general inventive concept, the first lower solder bumps 5 are interposed between the upper surface of the lower package substrate 1 and a lower surface of the heat sink 60b to electrically connect the lower package substrate 1 and the heat sink 60b.

In FIGS. 14 to 16, the heat sinks 60a and 60b may have a function of shielding electromagnetic interference (EMI) besides the heat release function. Accordingly, malfunctions of the semiconductor packages (e.g., lower semiconductor package 101 and/or upper semiconductor package 102) can be minimized and/or prevented.

The above-described semiconductor packaging technology may be applied to various kinds of semiconductor elements and package modules.

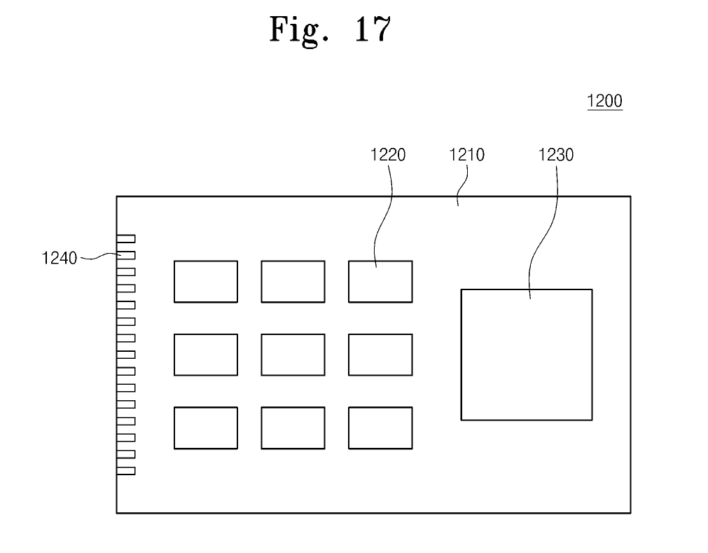

FIG. 17 illustrates an exemplary package module 1200 including a semiconductor package to which exemplary embodiments of the present general inventive concept is applied. Referring to FIG. 17, the package module 1200 may be provided in a form like a semiconductor integrated circuit chip 1220 and a semiconductor integrated circuit chip 1230 packaged, for example, in a quad flat package type. The package module 1200 may be formed by installing semiconductor devices 1220 and 1230, which the semiconductor packaging of one or more of the exemplary embodiments of the present general inventive concept as illustrated in FIGS. 1-16 and as disclosed above is applied to, in a substrate 1210. The package module 1200 may be connected to an external electronic device through external connection terminals 1240 included in one side of the substrate 1210.

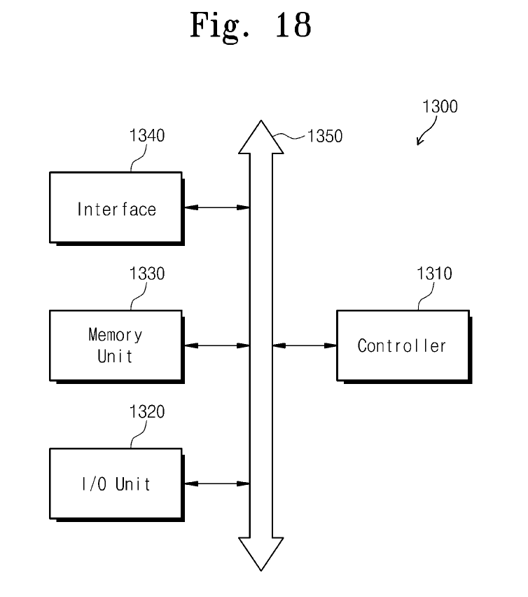

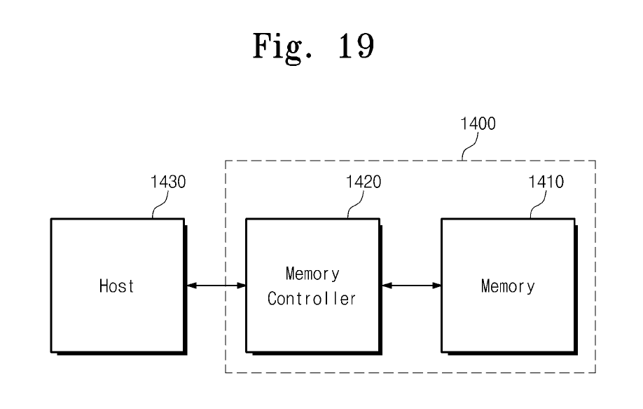

The semiconductor packaging of one or more of the exemplary embodiments of the present general inventive concept as illustrated in FIGS. 1-16 and as disclosed above may be applied to an electronic system. FIG. 18 is a block diagram illustrating an exemplary electronic device including a semiconductor package to which exemplary embodiment of the present general inventive concept is applied. Referring to FIG. 18, the electronic system 1300 may include a controller 1310, an input and output (I/O) unit 1320, and a memory unit 1330. The controller 1310, the input and output unit 1320, and the memory unit 1330 may be combined through a bus 1350. The bus 1350 may be a data passing path. For example, the controller 1310 may include at least one microprocessor, a digital signal processor, a microcontroller, a field programmable gate array, a programmable logic device, an integrated circuit, and at least any one of logic elements capable of performing the same functions as those. The controller 1310 and the memory unit 1330 may include a semiconductor package as described above in connection with FIG. 1-16 according to exemplary embodiments of the present general inventive concept. The input and output unit 1320 may include at least one of a key pad, a keyboard, a touch screen, and a display device. The memory unit 330 is a device to store data. The memory unit 1330 may store data and/or instructions executed by the controller 1310. The memory unit 1330 may include volatile memory devices and/or nonvolatile memory devices. Alternatively, the memory unit 1330 may be formed of flash memories. For example, a flash memory, which exemplary embodiments according to the present general inventive concept as discussed above are applied to, is mounted to an information processing system, such as a mobile device or a desktop computer. These flash memories may be formed of semiconductor disk devices (e.g., a solid state drive (SSD)). In this case, the electronic system 1300 may stably store a large capacity of data to the flash memory system. The electronic system 1300 may transmit the data to a communication network via a wired and/or wireless communications link, or may further include an interface 1340 to receive the data from the communication network. The interface 1340 may be a wired and/or wireless type of communications interface. For example, the interface 1340 may include an antenna, or a wired and/or wireless transceiver. Although not illustrated, it is obvious to those skilled in the art that the electronic system 1300 may further include an application chipset, an image sensor, a camera image processor and/or other image processor, and an input and output unit.

The electronic system 1300 may be a mobile system, a personal computer, an industrial computer or a logic system performing various functions. For example, the mobile system may be any one of a personal digital assistant, a mobile computer, a tablet computer, a web tablet, a mobile phone, a wireless phone, a laptop computer, a memory card, a digital music system, a digital media player, and/or an information transmission/reception system. Where the electronic system 1300 performs wireless communication, the electronic system 1300 may communicate in, for example, a communication interface protocol employed in the 3^{rd} generation communication system such as code-division multiple access (CDMA), global system for mobile communications (GSM), north American digital cellular (NADC), extended-time division multiple access (E-TDMA), wideband CDMA (WCDMA), and CDMA2000.

A semiconductor device to which the above-described exemplary embodiments of the present general inventive concept are applied may be provided in a memory card. FIG. 19 is a block diagram of an exemplary memory system including a semiconductor package to which the exemplary embodiments of the present general inventive concept are applied. Referring to FIG. 19, the memory card 1400 may include a nonvolatile memory 1410 and a memory controller 1420. The nonvolatile memory 1410 may store data, and the memory controller 1420 may read the stored data. The nonvolatile memory 1410 may include at least any one of nonvolatile memories to which the exemplary embodiments of the present general inventive concept are applied. The memory controller 1420 may control the nonvolatile memory 1410 in order to read the stored data from and write data to the nonvolatile memory 1410 in response to a read/write request by a host 1430.

According to the PoP device of the present general inventive concept, a thermal interface material layer is interposed between a lower semiconductor chip and an upper package substrate, and a heat sink is disposed on an upper semiconductor package substrate. The thermal interface material layer is interposed between the lower semiconductor chip, which is a logic chip that can generate heat, and the upper package substrate. Through this, since the heat generated by the lower semiconductor chip is transferred to the heat sink on the upper semiconductor package substrate, heat release can be increased and/or maximized. Accordingly, an operation speed can be improved and malfunction limitation of the elements (e.g., due to overheating of the upper and/or lower semiconductor chips) can be reduced and/or solved.

The above-disclosed subject matter is to be considered illustrative and not restrictive, and the appended claims are intended to cover all such modifications, enhancements, and other embodiments, which fall within the true spirit and scope of the present general inventive concept. Thus, to the maximum extent allowed by law, the scope of the present general inventive concept is to be determined by the broadest permissible interpretation of the following claims and their equivalents, and shall not be restricted or limited by the foregoing detailed description.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A package on package (PoP) device comprising:
a lower semiconductor package comprising a lower package substrate, and a lower semiconductor chip mounted on the lower package substrate;
an upper semiconductor package comprising an upper package substrate disposed on the lower semiconductor package, and an upper semiconductor chip mounted on the upper package substrate;
a first thermal interface material layer interposed between the lower semiconductor chip and the upper package substrate; and
a heat sink disposed on the upper semiconductor chip.

2. The PoP device of claim 1, further comprising:
a second thermal interface material layer interposed between the upper semiconductor chip and the heat sink.

3. The PoP device of claim 2, wherein the second thermal interface material layer directly contacts the upper semiconductor chip.

4. The PoP device of claim 3, wherein the upper semiconductor chip comprises first and second upper semiconductor chips sequentially stacked,
wherein the first upper semiconductor chip is mounted on the upper package substrate in a wire bonding method, and
the second upper semiconductor chip is mounted on the first upper semiconductor chip in a flip chip bonding method.

5. The PoP device of claim 4, wherein the first and second upper semiconductor chips are identical to each other and symmetrically disposed on one another.

6. The PoP device of claim 3, further comprising:
an upper mold layer covering side surfaces of the upper package substrate and the upper semiconductor chip,
wherein the upper mold layer comprises an upper surface that is coplanar with an upper surface of the upper semiconductor chip.

7. The PoP device of claim 2, wherein the upper semiconductor package further comprises:
an upper mold layer covering the package substrate and the upper semiconductor chip and being interposed between the second thermal interface material layer and the upper semiconductor chip.

8. The PoP device of claim 2, wherein the first and second thermal interface material layers include an adhesion layer, a thermal grease, or a thermal epoxy, and at least one of the first and second thermal interface material layers comprises metal solid particles.

9. The PoP device of claim 1, wherein the lower semiconductor package further comprises:
a lower mold layer covering side surfaces of the lower package substrate and the lower semiconductor chip,
wherein the lower mold layer comprises an upper surface that is coplanar with an upper surface of the lower semiconductor chip.

10. The PoP device of claim 1, wherein the heat sink is extended to cover side surfaces of the upper and lower semiconductor packages.

11. The PoP device of claim 1, wherein the heat sink comprises a plurality of protruding pins.

12. The PoP device of claim 1, wherein the lower semiconductor chip is a logic chip, and the upper semiconductor chip is a memory chip.

13-16. (canceled)

17. An electronic apparatus comprising:
a memory device comprising a package on package (PoP) device including:
a lower semiconductor package comprising a lower package substrate, and a lower semiconductor chip mounted on the lower package substrate;
an upper semiconductor package comprising an upper package substrate disposed on the lower semiconductor package, and an upper semiconductor chip mounted on the upper package substrate;
a first thermal interface material layer interposed between the lower semiconductor chip and the upper package substrate; and
a heat sink disposed on the upper semiconductor chip; and
a controller electrically connected to at least one of the lower semiconductor package and the upper semiconductor package to read from and write to at least one of the lower semiconductor chip and the upper semiconductor chip.

18. The electronic apparatus of claim 17,
wherein the heat sink has sides extended to cover side surfaces of the upper semiconductor packages,
the electronic apparatus further comprises:
lower solder bumps disposed on the lower package substrate so as to be interposed between an upper surface of the lower package substrate and a lower surface of the extended sides of the heat sink to electrically connect the lower package substrate and the heat sink.

19. The electronic apparatus of claim 17, further comprising:
a second thermal interface layer that is interposed between the upper semiconductor chip and the heat sink.

20. The electronic apparatus of claim 17, wherein the heat sink covers side surfaces of the upper and lower semiconductor packages.
